(19) United States
(12) Patent Application Publication
(10) Pub. No.: US 2026/0219566 A1
(43) Pub. Date: Jul. 30, 2026

(54) REFLECTIVE MASK BLANK, METHOD FOR PRODUCING REFLECTIVE MASK BLANK, REFLECTIVE MASK, AND METHOD FOR PRODUCING REFLECTIVE MASK

(71) Applicant: AGC Inc., Tokyo (JP)

(72) Inventors: Yusuke ONO, Koriyama-shi (JP); Hiroaki IWAOKA, Koriyama-shi (JP); Taiga FUDETANI, Koriyama-shi (JP)

(73) Assignee: AGC Inc., Tokyo (JP)

(21) Appl. No.: 19/574,096

(22) Filed: Mar. 20, 2026

Related U.S. Application Data
(63) Continuation of application No. PCT/JP2024/029978, filed on Aug. 23, 2024.

(30) Foreign Application Priority Data
Jun. 29, 2023 (JP) 2023-169979
Jan. 25, 2024 (JP) 2024-009653

(51) Int. Cl. G03F 1/24; G03F 1/54

(52) U.S. Cl. CPC G03F 1/24; G03F 1/54

(57) ABSTRACT

A reflective mask blank having a conductive film with little transmittance variation in light transmittance at 632 nm and 1064 nm, and excellent flatness is provided. A reflective mask blank for EUV lithography comprising: a substrate; a conductive film provided on one side of the substrate; a multilayer reflective film to reflect EUV light, provided on the other side of the substrate; and an absorber film provided on a side of the multilayer reflective film opposite to the substrate.

### CROSS-REFERENCE TO RELATED APPLICATIONS

This application is a continuation of PCT Application No. PCT/JP2024/029976 filed on Aug. 23, 2024, which is based upon and claims the benefit of priority from Japanese Patent Application No. 2023-169979 filed on Sep. 29, 2023 and Japanese Patent Application No. 2024-009653 filed on Jan. 25, 2024. The contents of those applications are incorporated herein by reference in their entireties.

### TECHNICAL FIELD

The present invention relates to a reflective mask used for exposure to EUV (Extreme Ultra Violet) during the exposure process in semiconductor manufacturing (called EUV lithography), a method for producing the reflective mask, a reflective mask blank, which is an unpatterned reflective mask, and a method for producing the reflective mask blank.

Herein, a reflective mask blank for EUV lithography is also referred to simply as “a reflective mask blank”, and a reflective mask for EUV lithography is also referred to simply as “a reflective mask”.

### BACKGROUND ART

Recent years have seen studies of EUV lithography, which uses EUV light with a center wavelength of about 13.5 nm as a light source, for further miniaturization of semiconductor devices.

In EUV lithography, reflective optical system and a reflective mask are used due to the nature of EUV light. The reflective mask has a multilayer reflective film provided on a substrate to reflect EUV light and a patterned absorber film provided on the multilayer reflective film to absorb EUV light.

The EUV light incident on the reflective mask from a lighting system of the exposure equipment is reflected in areas without the absorber film (exposed areas) and is absorbed in areas covered with the absorber film (covered areas). By projection of the reflected light through a reduction imaging optical system of the exposure equipment, the mask pattern is transferred onto a resist on a wafer, and a resist pattern is developed by subsequent processes.

Meanwhile, reflective masks and reflective mask blanks with an unpatterned absorber film are usually provided with a conductive film formed on the back side of the substrate opposite to the absorber film for electrostatic chucking.

For example, Patent Document 1 discloses a reflective mask blank having a conductive film comprising at least one element selected from the group consisting of tantalum and chromium and nitrogen.

### PRIOR ART DOCUMENTS

### Patent Documents

Patent Document 1: JP-A-2021-015295

### DISCLOSURE OF INVENTION

### Technical Problem

For manufacture of reflective masks, reflective mask blanks need to have high flatness so that the mask pattern is transferred as intended. By high flatness, flat reflective mask blank without warping is meant.

Distortion of the substrate due to the internal stress in the multilayer reflective film or the absorber film can be mitigated by irradiating reflective mask blanks and reflective masks with a laser beam having a wavelength of 632 nm or a laser beam having a wavelength of 1064 nm from the conductive film side.

When distortion of the substrate is mitigated by irradiating a laser beam, because very fine tuning of the dose of the laser beam over the surface is necessary, the conductive film is required to transmit the laser beam having the above-mentioned wavelength uniformly over the surface.

The present inventors assessed the reflective mask blank disclosed in Patent Document 1, and found that it sometimes failed to simultaneously achieve the currently required levels of flatness and uniformity in laser light transmittance and needs improvement.

In view of the above-mentioned problems, the present invention aims to provide a reflective mask blank having a conductive film with little transmittance variation in light transmittance at 632 nm and 1064 nm, and excellent flatness.

The present invention also aims to provide a method for producing the above-mentioned reflective mask blank, a reflective mask and a method for producing a reflective mask.

### Solution to Problem

As a result of intensive studies on the above-mentioned problems, the present inventors found it important to adjust the content of certain elements in the conductive film and in-plane adjustment of the thickness of the conductive film and have accomplished the present invention.

Namely, the present inventors have found the following solutions to the above-mentioned problems.

[1] A reflective mask blank for EUV lithography comprising:
a substrate;
a conductive film provided on one side of the substrate;
a multilayer reflective film to reflect EUV light, provided on the other side of the substrate; and
an absorber film provided on a side of the multilayer reflective film opposite to the substrate,
wherein the conductive film comprises at least one element selected from the group consisting of tantalum and chromium,
wherein the total content of nitrogen and boron in the conductive film is more than 33 atomic % relative to all the atoms in the conductive film,
wherein the conductive film has a thickness of from 20 to 150 nm,
wherein the conductive film is thicker at the center of the substrate than at a peripheral portion of the substrate, and
wherein the maximum in-plane thickness variation of the conductive film is from 0.30 to 1.00 nm.

[2] The reflective mask blank for EUV lithography according to [1], wherein the content of nitrogen in the conductive film is from 35 to 65 atomic % relative to all the atoms in the conductive film.

[3] The reflective mask blank for EUV lithography according to [1] or [2], wherein the content of boron in the conductive film is more than 0 atomic % and at most 35 atomic % relative to all the atoms in the conductive film.

[4] The reflective mask blank for EUV lithography according to any one of [1] to [3], wherein the conductive film has an electric resistivity of from 0.05 to 0.35 mΩ·cm.

[5] The reflective mask blank for EUV lithography according to any one of [1] to [4], wherein the surface roughness of the surface of the conductive film opposite to the substrate is at most 0.60 nm.

[6] The reflective mask blank for EUV lithography according to any one of [1] to [5], wherein the conductive film has a multilayer structure comprising at least two layers including an outermost layer comprising tantalum and at least one element selected from the group consisting of nitrogen and oxygen located farthest from the substrate.

[7] The reflective mask blank for EUV lithography according to [6], wherein the content of oxygen in the outermost layer is from 20 to 60 atomic % relative to all the atoms in the outermost layer.

[8] The reflective mask blank for EUV lithography according to [6] or [7], wherein the content of oxygen in the outermost layer is from 40 to 50 atomic % relative to all the atoms in the outermost layer.

[9] The reflective mask blank for EUV lithography according to any one of [1] to [8], wherein when the light transmittance of the conductive film is measured at different three points at 632 nm, the arithmetic mean of the transmittance values thus obtained at these three points is designated as the average transmittance at 632 nm, and the difference between the maximum and minimum transmittance values at these three points is designated as the maximum transmittance difference at 632 nm, the ratio of the maximum transmittance difference of the conductive film at 632 nm to the average transmittance of the conductive film at 632 nm is less than 2.0%.

[10] The reflective mask blank for EUV lithography according to any one of [1] to [9], wherein when the light transmittance of the conductive film measured at different three points at 1064 nm, the arithmetic mean of the transmittance values thus obtained at these three points is designated as the average transmittance at 1064 nm, and the difference between the maximum and minimum transmittance values at these three points is designated as the maximum transmittance difference at 1064 nm, the ratio of the maximum transmittance difference of the conductive film at 1064 nm to the average transmittance of the conductive film at 1064 nm is less than 2.0%.

[11] A reflective mask for EUV lithography having an absorber pattern obtained by patterning the absorber film of the reflective mask blank for EUV lithography as defined in any one of [1] to [10].

[12] A method for producing a reflective mask for EUV lithography, comprising a step of patterning the absorber film of the reflective mask blank for EUV lithography as defined in any one of [1] to [10].

[13] A method for producing a reflective mask blank for EUV lithography as defined in any one of [1] to [10], comprising forming a conductive film on one surface of a substrate,
forming a multilayer reflective film which reflects EUV light on the other surface of the substrate, and
forming an absorber film on the surface of the multilayer reflective film opposite to the substrate,
wherein the conductive film is formed in the presence of nitrogen gas under a pressure of 0.1 to 0.4 Pa.

[14] A substrate with a conductive film, comprising a substrate; and
a conductive film provided on one surface of the substrate,
wherein the conductive film comprises at least one element selected from the group consisting of tantalum and chromium,
wherein the total content of nitrogen and boron in the conductive film is more than 33 atomic % relative to all the atoms in the conductive film,
wherein the conductive film has a thickness of from 20 to 150 nm,
wherein the conductive film is thicker at the center of the substrate than at the peripheral portion of the substrate, and
wherein the maximum in-plane thickness variation of the conductive film is from 0.30 to 1.00 nm.

[15] The substrate with a conductive film according to [14], wherein the content of nitrogen in the conductive film is from 35 to 65 atomic % relative to all the atoms in the conductive film.

[16] The substrate with a conductive film according to [14] or [15], wherein the content of boron in the conductive film is more than 0 atomic % and at most 35 atomic % relative to all the atoms in the conductive film.

[17] The substrate with a conductive film according to any one of [14] to [16], wherein the conductive film has an electric resistivity of from 0.05 to 0.35 mQ-cm.

[18] The substrate with a conductive film according to any one of [14] to [17], wherein the conductive film has a multilayer structure comprising at least two layers including an outermost layer comprising at least one element selected from the group consisting of tantalum, nitrogen and oxygen located farthest from the substrate.

[19] The substrate with a conductive film according to [18], wherein the content of oxygen in the outermost layer is from 20 to 60 atomic % relative to all the atoms in the outermost layer.

[20] The substrate with a conductive film according to [18], wherein the content of oxygen in the outermost layer is from 40 to 50 atomic % relative to all the atoms in the outermost layer.

[21] The substrate with a conductive film according to any one of [14] to [20], wherein when the light transmittance of the conductive film measured at different three points at 632 nm, the arithmetic mean of the transmittance values thus obtained at these three points is designated as the average transmittance at 632 nm, and the difference between the maximum and minimum transmittance values at these three points is designated as the maximum transmittance difference at 632 nm, the ratio of the maximum transmittance difference of the conductive film at 632 nm to the average transmittance of the conductive film at 632 nm is less than 2.0%.

[22] The substrate with a conductive film according to any one of [14] to [21], wherein when the light transmittance of the conductive film measured at different three points at 1064 nm, the arithmetic mean of the transmittance values thus obtained at these three points is designated as the average transmittance at 1064 nm, and the difference between the maximum and minimum transmittance values at these three points is designated as the maximum transmittance difference at 1064 nm, the ratio of the maximum transmittance difference of the conductive film at 1064 nm to the average transmittance of the conductive film at 1064 nm is less than 2.0%.

### Advantageous Effects of Invention

According to the present invention, it is possible to provide a reflective mask blank with little variation in light transmittance at 632 nm and 1064 nm, and excellent flatness.

According to the present invention, it is also possible to provide a method for producing the above-mentioned reflective mask blank, a reflective mask and a method for producing a reflective mask.

### BRIEF DESCRIPTION OF DRAWINGS

FIG. 1 is a schematic view of an embodiment of the reflective mask blank of the present invention.

FIG. 2 is a plan view of the reflective mask blank of the present invention illustrated in FIG. 1 from the conductive film side.

FIGS. 3A-3D are schematic views of an example of a method for producing a reflective mask using the reflective mask blank of the present invention.

### DESCRIPTION OF EMBODIMENTS

Now, the present invention will be described in detail.

Although the features of the present invention will sometimes be described in reference to typical embodiments of the present invention, the present invention is not limited to these embodiments.

Each term used in the present specification has the following meaning.

In the present specification, a numerical range expressed using “to” includes the figures before and after “to” as lower and upper limits.

In the present specification, elements such as boron, carbon, nitrogen, oxygen, silicon, titanium, chromium, zirconium, niobium, molybdenum, ruthenium, rhodium, palladium, tantalum, rhenium, iridium and platinum may be respectively expressed by their corresponding chemical symbols (such as B, C, N, O, Si, Ti, Cr, Zr, Nb, Mo, Ru, Rh, Pd, Ta, Re, Ir and Pt).

### <Reflective Mask Blank>

The reflective mask blank of the present invention comprises a substrate, a conductive film provided on one side of the substrate and an absorber film provided on a side of the multilayer reflective film which reflects EUV light opposite to the substrate. In the reflective mask blank of the present invention, the conductive film comprises at least one element selected from the group consisting of tantalum and chromium, and the total content of nitrogen (N) and boron (B) in the conductive film is more than 33 atomic % relative to all the atoms in the conductive film. In the reflective mask blank of the present invention, the conductive film has a thickness of from 20 to 150 nm, and the conductive film is thicker at the center of the substrate than at a peripheral portion of the substrate, and the maximum in-plane thickness variation of the conductive film is from 0.30 to 0.80 nm.

The reflective mask blank of the present invention will be described in more detail below in reference to the drawings.

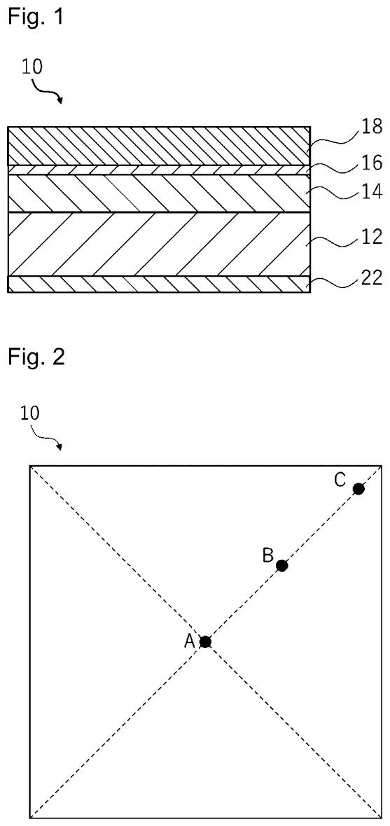

FIG. 1 is a cross-sectional view of one embodiment of the reflective mask blank of the present invention. The reflective mask blank 10 in FIG. 1 has a conductive film 22, a substrate 12, a multilayer reflective film 14, a capping film 16 and an absorber film 18 in this order.

The conductive film 22 comprises the above-mentioned elements in the above-mentioned amounts. The conductive film 22 satisfies the above-mentioned thickness requirements.

The capping film 16 in FIG. 1 may be omitted.

The reflective mask blank 10 may have a hard mask film, which will be described later, on the side of the absorber film 18 opposite to the substrate 12.

The present inventors speculate, though not for sure, the mechanism behind the little variation in light transmittance at 632 nm and 1064 nm of the conductive film in the reflective mask blank of the present invention and the excellent flatness of the conductive film in the reflective mask blank of the present invention, as follows.

The conductive film in the reflective mask blank of the present invention transmits light at 632 nm and 1064 nm because the total content of N and B is more than 33 atomic % relative to all the atoms in the conductive film and its thickness is within the above-mentioned range. The present inventors found that the variation in light transmittance of the conductive film at 632 nm and 1064 nm is decreased by making the conductive film thicker at the center of the substrate than at the peripheral portion of the substrate while keeping the maximum thickness variation within the above-mentioned range.

It is also speculated that when the total content of N and B is more than 33 atomic % relative to all the atoms in the conductive film, a reflective mask blank with excellent flatness is obtained because the conductive film generates a stress large enough to balance out the stress generated by the multilayer reflective film and the absorber film on the opposite side of the substrate.

Now, the components of the reflective mask blank of the present invention will be described below.

### [Substrate]

The substrate in the reflective mask blank of the present invention preferably has a low thermal expansion coefficient. When the thermal expansion coefficient of the substrate is low, it is possible to suppress a distortion of the absorber pattern due to heat during exposure to EUV light.

The thermal expansion coefficient of the substrate at 20° C. is preferably 0±1.0×10⁻⁷/° C., more preferably 0±0.3×10⁻⁷/° C.

As a material having a low thermal expansion coefficient, SiO₂—TiO₂ glass may be mentioned. The material for the substrate is, however, not limited thereto. Substrates of crystallized glass precipitated from a β-quartz solid solution, silica glass, metallic silicon, metals and the like can also be used.

The SiO₂—TiO₂ glass is preferably silica glass having a SiO₂ content of from 90 to 95 mass % and a TiO₂ content of from 5 to 10 mass %. Glass with a TiO₂ content of from 5 to 10 mass % has a linear expansion coefficient of substantially 0 around room temperature and hence does not change dimensionally around room temperature. The SiO₂—TiO₂ glass may contain trace components other than SiO₂ and TiO₂.

The surface (hereinafter also referred to as “first main surface”) of the substrate on which the multilayer reflective film is provided preferably has high surface smoothness. The surface smoothness of the first main surface can be evaluated by surface roughness. The surface roughness of the first main surface is preferably 0.15 nm or less in terms of the root mean square roughness Rq. Here, the surface roughness can be measured under an atomic force microscope; and the surface roughness refers to the root mean square roughness Rq according to JIS B0601.

From the viewpoint of improving the pattern transfer precision and pattern placement precision of a reflective mask obtained from the reflective mask blank, the first main surface is preferably processed to a certain level of flatness. The flatness of the substrate in a designated region (for example, a 132 mm×132 mm region) of the first main surface is preferably 100 nm or less, more preferably 50 nm or less, still more preferably 30 nm or less. The flatness can be measured with a FUJINON flatness interferometer.

The size and thickness of the substrate are determined appropriately according to the mask design. For example, the substrate may be 6 inches (152 mm) square and 0.25 inches (6.3 mm) thick.

The substrate is usually rectangular or square in shape.

Further, the substrate preferably has high rigidity to prevent distortion due to stresses generated by the films formed on it (the multilayer reflective film, absorber film or the like). For example, the substrate preferably has a Young's modulus of 65 GPa or higher.

### [Multilayer Reflective Film]

The multilayer reflective film in the reflective mask blank of the present invention is not particularly limited so far as it has desired characteristics as the reflective film of a EUV mask blank. The multilayer reflective film preferably has high EUV reflectance. Specifically, when the surface of the multilayer reflective film is irradiated with EUV light at an incident angle of 6°, the maximum value of the reflectance at EUV wavelengths around 13.5 nm is preferably 60% or higher, more preferably 65% or higher. Even when the capping film is formed on the multilayer reflective film, the maximum value of the reflectance at EUV wavelengths around 13.5 nm is still preferably 60% or higher, more preferably 65% or higher.

With a view to achieving high EUV reflectance, the multilayer reflective film generally comprises high refractive index layers having a high refractive index to EUV light and low refractive index layers having a low refractive index to EUV light stacked alternately plural times.

The multilayer reflective film may be a stack of plural units each comprising a high refractive index layer and a low refractive index layer in this order from the substrate side or may be a stack of plural units each comprising a low refractive index layer and a high refractive index layer in this order from the substrate side.

As the high refractive index layers, layers containing Si can be used. As Si-containing materials, not only elemental Si but also Si compounds containing Si and at least one selected from the group consisting of B, C, N and O may be used. The use of Si-containing high refractive index layers enables provision of a reflective mask with high EUV reflectance.

As the low refractive index layers, layers containing a metal selected from the group consisting of Mo, Ru, Rh and Pt or an alloy thereof can be used.

It is common to use Si in the high refractive index layers and use Mo in the low refractive index layers. In other words, a Mo/Si multilayer reflective film is most commonly used. The multilayer reflective film is, however, not limited to thereto, and may be a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo multilayer reflective film, a Si/Ru/Mo/Ru multilayer reflective film or the like.

The thickness of each of the layers and the number of repeating units of layers constituting the multilayer reflective film are selected appropriately depending on the film materials used and the EUV reflectance necessary for the reflective film. For example, in the case of a Mo/Si multilayer reflective film, from 30 to 60 repeating units each comprising a Mo layer having a thickness of 2.3±0.1 nm and a Si layer having a thickness of 4.5±0.1 nm are stacked to obtain a multilayer reflective film having a maximum EUV reflectance of at least 60%.

Each of the layers constituting the multilayer reflective film can be formed with a desired thickness by a known film formation method such as magnetron sputtering, ion beam sputtering or the like. For example, when a multilayer reflective film is formed by ion beam sputtering, ion particles supplied from an ion source are ejected towards a target made of a high refractive index material or a target made of a low refractive index material. In the case of formation of a Mo/Si multilayer reflective film by ion beam sputtering, a cycle of formation of a Si layer with a predetermined thickness using a Si target and formation of a Mo layer with a predetermined thickness using a Mo target is repeated on the substrate from 30 to 60 times.

### [Capping Film]

The reflective mask blank of the present invention may have a capping film between the multilayer reflective film and the absorber film. The capping film is formed so as to protect the multilayer reflective film from damage by etching (usually dry etching) during patterning of the absorber film.

As the material to meet the above-mentioned purpose, a material containing at least one element selected from the group consisting of Ru and Rh may be mentioned. Namely, the capping film preferably comprises at least one element selected from the group consisting of Ru and Rh.

Specific examples of the above-mentioned material include elemental Ru metal, a Ru alloy containing Ru and at least one metal selected from the group consisting of Si, Ti, Nb, Rh and Zr, and Rh-based materials such as elemental Rh metal, a Rh alloy containing Rh and at least one metal selected from the group consisting of Si, Ti, Nb, Ru, Ta and Zr, a Rh-containing nitride containing the above-mentioned Rh alloy and nitrogen and a Rh-containing oxynitride containing the above-mentioned Rh alloy, nitrogen and oxygen.

As the material to meet the above-mentioned purpose, Al, a nitride containing these metals and nitrogen, Al₂O₃ and the like may also be mentioned.

Among them, elemental Ru metal, a Ru alloy, elemental Rh metal or a Rh alloy is preferred as the material to meet the above-mentioned purpose. As the Ru alloy, a Ru—Si alloy is preferred, and as the Rh alloy, a Rh—Si alloy is preferred.

The thickness of the capping film is not particularly limited so far as the capping film fulfills its function. The thickness of the capping film is preferably from 1 to 10 nm, more preferably from 1.5 to 6 nm, still more preferably from 2 to 5 nm with a view to ensuring reflection of EUV light on the multilayer reflective film with a certain level of reflectance.

The capping film is preferred to be made of elemental Ru metal, a Ru alloy, elemental Rh metal or a Rh alloy and has a thickness within the above-mentioned preferred range.

The capping film may be a monolayer film or a multilayer film comprising plural layers. When the capping film is a multilayer film, each layer in the multilayer film is preferably made of the above-mentioned preferable material. When the capping film is a multilayer film, the total thickness of the layers in the multilayer film is preferably within the above-mentioned preferable thickness range for the capping film.

When the capping film is a multilayer film, it is preferred that the layer closest to the absorber film contains Rh. When the layer closest to the absorber film contains Rh, it is preferred that at least one of the other layers contains Ru.

The capping film can be formed by a known film-forming method such as DC sputtering, magnetron sputtering and ion beam sputtering. When a Ru film is formed by magnetron sputtering, it is preferred to use a Ru target as the target and Ar gas as the sputtering gas. When a Rh film is formed by magnetron sputtering, it is preferred to use a Rh target as the target and Ar gas as the sputtering gas.

### [Absorber Film]

The absorber film in the reflective mask blank of the present invention is required to enable the EUV light reflected from the multilayer reflective film to produce a high contrast image after patterning of the absorber film.

The patterned absorber film (absorber pattern) may be used in a binary mask having an absorber pattern which absorbs EUV light, or may be used in a phase shift mask having an absorber pattern which reflects EUV light to produce a high contrast image through the interference with the EUV light reflected from the multilayer reflective film.

When the absorber pattern is used in a binary mask, the absorber film has to absorb EUV light and have low EUV reflectance, specifically speaking, the absorber film preferably has a EUV reflectance of at most 2% at EUV wavelengths around 13.5 nm, when irradiated with EUV light.

The absorber film contains at least one metal selected from the group consisting of Ta, Ti, Sn and Cr and may further contain at least one component selected from the group consisting of O, N, B, Hf and H. Especially, the absorber film is preferred to contain Ta and further contain either N or B. Inclusion of N or B makes the absorber film amorphous or microcrystalline.

The absorber film is preferred to be amorphous in order to improve smoothness and flatness. An absorber film having a smoother and flatter surface can make an absorber pattern with low edge roughness and high dimensional precision.

When the absorber pattern is used in a binary mask, the thickness of the absorber film is preferably from 40 to 70 nm, more preferably from 50 to 65 nm.

When the absorber film pattern is used in a phase shift mask, the EUV reflectance of the absorber film is preferably at least 2%. In order to produce sufficient phase shift effect, the EUV reflectance of the absorber film is preferably from 9 to 15%. When such an absorber film is used in a phase shift mask, an optical image can be formed on a wafer with higher contrast and a wide exposure margin.

In the case of a phase shift mask, materials such as elemental Ru metal, a Ru alloy containing Ru and at least one metal selected from the group consisting of Cr, Au, Pt, Re, Hf, Ta, W, Ti and Si, an alloy of Ta and Nb, an oxide containing a Ru alloy or TaNb alloy and oxygen, a nitride containing a Ru alloy or TaNb alloy and nitrogen, an oxynitride containing a Ru alloy or TaNb alloy, oxygen and nitrogen, a compound containing at least one elemental metal selected from the group consisting of Pd, Ir, Pt, Ag, Ni and Co and the like may be mentioned. When the absorber pattern is used in a phase shift mask, the thickness of the absorber film is preferably from 30 to 60 nm, more preferably from 35 to 55 nm.

The absorber film may be a monolayer film or a multilayer film comprising plural layers. When the absorber film is a monolayer film, a mask blank can be produced in fewer steps and hence with higher production efficiency. When the absorber film is a multilayer film, the absorber film may have a layer which acts as an anti-reflective film during inspection of the absorber pattern by irradiation with light (for example, at a wavelength of 193 to 248 nm) located opposite to the capping film.

As the material for such an anti-reflective film, a material containing Ta and O may, for example, be mentioned.

The absorber film can be formed by a known film-forming method such as magnetron sputtering and ion beam sputtering. For example, a Ta nitride film as an absorber film is formed by magnetron sputtering using a Ta target with a feed of a gas containing Ar gas or nitrogen gas.

### [Conductive Film]

The reflective mask blank of the present invention has a conductive film on the surface (second main surface) of the substrate opposite to the first main surface. The conductive film enables the reflective mask blank to be held onto an electrostatic chuck.

Now, the conductive film in the reflective mask blank of the present invention will be described in detail.

The conductive film in the reflective mask blank of the present invention comprises at least one element selected from the group consisting of Ta and Cr. The conductive film preferably comprises Ta in order to obtain a reflective mask blank with higher flatness.

The total content of N and B in the conductive film is more than 33 atomic % relative to all the atoms in the conductive film.

When the conductive film comprises N and B, the content of N in the conductive film is preferably from 35 to 65 atomic %, more preferably from 40 to 55 atomic %, relative to all the atoms in the conductive film.

When the conductive film comprises N and B, the content of B in the conductive film is preferably more than 0 atomic % and at most 45 atomic %, more preferably from 10 to 40 atomic %, relative to all the atoms in the conductive film. The content of B may be more than 0 atomic % and at most 35 atomic %, relative to all the atoms in the conductive film.

The content of each element in the conductive film is analyzed by X-ray photoelectron spectroscopy (XPS), specifically speaking, as described later in the Examples.

When the conductive film is a multilayer film, the content of each element in each layer of the conductive film is analyzed while the conductive film is etched from the surface of the conductive film opposite to the substrate, for example, by argon ion sputtering.

When the conductive film comprises N but does not comprise B, the content of N is preferably from 35 to 65 atomic %, more preferably from 40 to 60 atomic %, further preferably from 45 to 55 atomic %, relative to all the atoms in the conductive film.

When the conductive film does not comprise N but comprises B, the content of B is preferably more than 33 atomic % and at most 45 atomic %, more preferably from 35 to 40 atomic %, relative to all the atoms in the conductive film. The content of B may be at most 35 atomic % relative to all the atoms in the conductive film.

In addition to Cr, Ta, N and B, the conductive film may comprise other elements such as C, O, fluorine (F), hydrogen (H), silicon (Si) and Ar.

Specific examples of the material constituting the conductive film include CrN, CrON, CrB, CrBN, CrCN, TaN, TaON, TaB, TaBN, TaCN, CrTaN and the like, and preferred is CrN, TaN or TaBN. The expression “CrON” refers to a material containing Cr, O and N, and the ratios of these elements are not particularly limited as long as the above-mentioned requirements are satisfied.

The conductive film may have a monolayer structure or a multilayer structure.

When the conductive film has a multilayer structure, the conductive film preferably comprises at most 4 layers, more preferably at most 3 layers, further preferably two layers, although there are no particular restrictions on the number of layers.

When the conductive film has a multilayer structure, it contains at least one element selected from the group consisting of Ta and Cr in any of the layers constituting the conductive film, preferably in all the layers constituting the conductive film.

When the conductive film has a multilayer structure, the conductive film has the above-mentioned content of N and the above-mentioned content of B as a whole.

When the conductive film has a multilayer structure and comprises N but does not comprise B, the content of N is preferably from 35 to 55 atomic %, more preferably from 40 to 50 atomic %, relative to all the atoms in the conductive film.

Of the layers in the conductive film, the outermost layer located farthest from the substrate preferably comprises Ta. The outermost layer is also preferred to comprise Ta and at least one element selected from the group consisting of N and O.

When the outermost layer comprises Ta and at least one element selected from the group consisting of N and O, the content of O is preferably from 20 to 60 atomic %, more preferably from 30 to 50 atomic %, particularly preferably from 40 to 50 atomic %, relative to all the atoms in the outermost layer.

The outermost layer does not have to comprise N.

The conductive film has a thickness of from 20 to 150 nm. When the conductive film has a multilayer structure, the total thickness of the layers constituting the conductive film is from 20 to 150 nm.

The thickness of the conductive film is preferably from 25 to 120 nm, more preferably from 30 to 100 nm in view of flatness.

The thickness of the conductive film is measured by X-ray reflectivity (XRR) and is calculated as described later.

When the conductive film has a multilayer structure, the ratio of the thickness of layer(s) comprising at least one element selected from the group consisting of Ta and Cr and having a total content of N and B higher than 33 atomic % to the total thickness of the conductive film is preferably at least 0.50, more preferably at least 0.70, further preferably at least 0.80. The upper limit of the ratio is less than 1.00 and is usually 0.95 or below.

The reflective mask blank of the present invention is thicker at the center of the substrate (hereinafter referred to simply as “the center”) than at a peripheral portion of the substrate (hereinafter referred to simply as “the peripheral portion”).

When the substrate is a square or a rectangle, the center of the substrate means the intersection of the two diagonals.

Herein, the peripheral portion of the substrate is defined as follows.

For a square or a rectangular substrate, when a planar coordinate system is supposed on the surface of the substrate with the coordinate origin at the center of the substrate, the X axis parallel to one of the edges and the Y axis perpendicular to the X axis, the point expressed as (0.868 Lx, 0.868 Ly) is designated as the peripheral portion of the substrate, wherein Lx is the distance from the coordinate origin to the intersection between the X axis and an edge of the substrate, and Ly is the distance from the coordinate origin to the intersection between the Y axis and an edge of the substrate. The thickness at the peripheral portion may be measured anywhere in a 0.5 mm-radius circle centered at the peripheral portion. The thickness at the center of the substrate may be measured anywhere in a 0.5 mm-radius circle centered at the center of the substrate.

For example, for a 152 mm square substrate, the peripheral portion of the substrate is a point at a distance of 66 mm from the coordinate origin along the X axis and at a distance of 66 mm from the coordinate origin along the Y axis in a coordinate system centered at the intersection of the two diagonals of the substrate with the X axis parallel to one of the edges and the Y axis perpendicular to the X axis.

Namely, “the conductive film is thicker at the center of the substrate than at the peripheral portion of the substrate” means that the thickness of the conductive film at the center is larger than the thickness of the conductive film at the peripheral portion (at the above-mentioned point in the coordinate system).

The thicknesses of the conductive film at the center and at the peripheral portion are measured by XRR with SmartLab HTP manufactured by Rigaku Holdings Corporation, using CuKα line as the X ray radiation source at a tube voltage of 40 kV and a tube current of 30 mA with the help of the accessory analysis software (GlobalFit). In the XRR measurements, the conductive film is irradiated so that the center of the X ray beam is directed at the center of the substrate or the peripheral portion of the substrate.

While the center and peripheral portion of a square or rectangular substrate are defined as described above, the center of a circular substrate is defined as the center of the circle, and the peripheral portion of a circular substrate is defined as a point at a distance of 0.868 times the radius of the substrate from the center of the substrate.

The thickness of the conductive film is measured as described below.

First, the distance between the above-mentioned center and peripheral portion (along a diagonal of the substrate) is defined as Ld. Then, the thickness of the conductive film is measured at a point at a distance of 33Ld/66 from the center along a diagonal, the center and the peripheral portion as described above, and the arithmetic means of the three measured values is designated as the thickness of the conductive film. The thicknesses at the three points may be measured anywhere in a 0.5 mm-radius circle centered at these points.

For example, for a 152 mm square substrate, the thickness of the conductive film is measured by XRR at points expressed as (0,0), (33, 33) and (66, 66) in mm in a coordinate system centered at the intersection of the two diagonals of the substrate with the X axis parallel to one of the edges and the Y axis perpendicular to the X axis, and the arithmetic mean of the three measured values is designated as the thickness of the conductive film. In the case of a 152 mm square substrate, the above-mentioned three points are located as shown in FIG. 2. FIG. 2 is a plan view of the reflective mask blank of the present invention illustrated in FIG. 1 from the side covered with the conductive film 22, and points A to C are the points expressed as (0,0) (the center), (33, 33) and (66, 66) (the peripheral portion), respectively.

In the reflective mask blank of the present invention, the maximum in-plane thickness variation of the conductive film is from 0.30 to 0.80 nm.

Herein, the maximum thickness variation is obtained by subtracting the smallest from the largest among the thickness values obtained for measurement of the thickness of the conductive film.

The maximum thickness variation is preferably from 0.40 to 0.65 nm, more preferably from 0.50 to 0.60 nm in order to decrease the variation in light transmittance at 632 nm.

The maximum thickness variation among the thickness values obtained similarly at points expressed as (0, 0), (−33, 33) and (−66, 66) is preferably from 0.30 to 0.80 nm, more preferably within the above-mentioned preferred range.

The maximum thickness variation among the thickness values obtained similarly at points expressed as (0, 0), (−33, −33) and (−66, −66) is preferably from 0.30 to 0.80 nm, more preferably within the above-mentioned preferred range.

The maximum thickness variation among the thickness values obtained similarly at points expressed as (0, 0), (33, −33) and (66, −66) is preferably from 0.30 to 0.80 nm, more preferably within the above-mentioned preferred range.

The conductive film preferably has an electric resistivity of at most 0.35 mQ-cm so that the mask blank is firmly held onto an electrostatic chuck. The lower limit of the electric resistivity is usually 0.05 mQ-cm.

The electric resistivity of the conductive film is measured as described later in the Examples.

The surface roughness of the surface of the conductive film opposite to the substrate is preferably at most 0.60 nm, more preferably at most 0.50 nm. The surface roughness is usually 0.01 nm or more.

The surface roughness of the surface of the conductive film opposite to the substrate refers to root mean square roughness Rq and can be measured similarly to the surface roughness of the substrate, as specifically described later in the Examples.

Regarding the light transmittance of the conductive film at 632 nm, when the light transmittance of the conductive film is measured at the above-mentioned three points at 632 nm, the arithmetic mean of the transmittance values thus obtained at these three points is designated as the average transmittance at 632 nm, and the difference between the maximum and minimum transmittance values at these three points is designated as the maximum transmittance difference at 632 nm, the ratio of the maximum transmittance difference of the conductive film at 632 nm to the average transmittance of the conductive film at 632 nm is preferably less than 2.0%, more preferably less than 1.5%, further preferably less than 1.2%.

The light transmittance of the conductive film at 632 nm is measured as described below.

First, a substrate with a conductive film is prepared by forming a conductive film on a substrate or, in the case of a substrate already having a multilayer reflective film and an absorber film, by removing a multilayer reflective film and an absorber film. Next, the conductive film is illuminated with incident light normal to the surface of the conductive film, and the transmittance at 632 nm is calculated with a spectrophotometer.

As the spectrophotometer, “V-780” manufactured by JASCO Corporation is used with a wavelength range of 175 to 2000 nm.

Further, regarding the light transmittance of the conductive film at 1064 nm, when the light transmittance of the conductive film is measured at the above-mentioned three points at 1064 nm, the arithmetic mean of the transmittance values thus obtained at these three points is designated as the average transmittance at 1064 nm, and the difference between the maximum and minimum transmittance values at these three points is designated as the maximum transmittance difference at 1064 nm, the ratio of the maximum transmittance difference of the conductive film at 1064 nm to the average transmittance of the conductive film at 1064 nm is preferably less than 2.0%, more preferably less than 1.5%, further preferably less than 1.2%.

The light transmittance of the conductive film at 1064 nm is measured similarly to the light transmittance at 632 nm.

The conductive film may be formed by a known film-forming method such as sputtering including magnetron sputtering and ion beam sputtering, CVD or vacuum deposition, without any particular restrictions, as long as a conductive film which satisfies the above-mentioned requirements is formed. For formation of the conductive film, it is preferred to refer also to the production of a reflective mask blank described later.

### [Additional Films]

The reflective mask blank may comprise additional films such as a hard mask film. A hard mask film is preferably formed on a side of the absorber film opposite to the substrate.

A hard mask film is preferably a film made of a material highly resistant to dry etching, such as a Cr-based film or a Si-based film. As the material for a Cr-based film, Cr or a material comprising Cr and at least one element selected from the group consisting of O, N, C and H may be mentioned, and specifically, CrO, CrN or the like may be mentioned. As the material for a Si-based film, Si or a material comprising Si and at least one element selected from the group consisting of O, N, C and H may be mentioned, and specifically, SiO₂, SiON, SiN, SiO, Si, SiC, SiCO, SiCN, SiCON or the like may be mentioned. Formation of a hard mask film on the absorber film enables formation of an absorber pattern even with a small minimum line width by dry etching and is effective for miniaturization of absorber patterns.

### <Method for Producing Reflective Mask Blank>

The method for producing a reflective mask blank of the present invention comprises, for example, forming a conductive film on one surface of a substrate, forming a multilayer reflective film which reflects EUV light on the other surface of the substrate, and forming an absorber film on the surface of the multilayer reflective film opposite to the substrate, and the conductive film is formed in the presence of at least one gas selected from the group consisting of nitrogen gas or oxygen gas under a pressure of 0.1 to 0.4 Pa.

Formation of the conductive film in the presence of nitrogen gas means that the conductive film is formed in an atmosphere containing nitrogen gas (N₂ gas).

Formation of the conductive film in the presence of oxygen gas means that the conductive film is formed in an atmosphere containing oxygen gas (O₂ gas).

Formation of the conductive film in the presence of nitrogen gas and oxygen gas means that the conductive film is formed in an atmosphere containing nitrogen gas (N₂ gas) and oxygen gas (O₂ gas).

Formation of the conductive film under a pressure within the above-mentioned range means that the pressure in the space (for example, a chamber) where the conductive film is formed is within the above-mentioned range.

The conductive film is preferably formed by sputtering, especially magnetron sputtering.

The conductive film is formed while the pressure in the space where the conductive film is formed is kept at from 0.1 to 0.4 Pa. When the conductive film is formed by sputtering (preferably magnetron sputtering), the pressure in the chamber where the sputtering is conducted is controlled so as to be within the above-mentioned range.

The pressure control may be done by feeding a gas into the chamber at a controlled flow rate from a gas feeding means connected to the chamber while evacuating the chamber using a vacuum pump connected to the chamber. The feeding rate of the gas may be controlled by monitoring the pressure in the chamber indicated by a vacuum gauge installed in the chamber.

In the above-mentioned method, it is preferred to feed a mixed gas comprising a noble gas and at least one gas selected from the group consisting of nitrogen gas and oxygen gas. As the noble gas, Ne gas, Ar gas, Kr gas or Xe gas may be mentioned, and Ar is preferred. The content of nitrogen gas in a mixed gas is preferably from 5 to 50 vol %, more preferably from 10 to 30 vol %, relative to the total volume of the mixed gas.

The deposition rate during formation of the conductive film by sputtering (preferably by magnetron sputtering) is preferably from 0.5 to 20 nm/min, more preferably from 1 to 20 nm/min, further preferably from 2 to 10 nm/min, particularly preferably from 2 to 4.7 nm/min.

The power input during formation of the conductive film by magnetron sputtering is preferably from 500 to 1500 W, more preferably from 700 to 1200 W.

In the case of a conductive film having a multilayer structure comprising at least two layers, after a first layer closest to the substrate was formed, the second and subsequent layers were formed under sputtering conditions similar to those used for formation of the first layer.

The multilayer reflective film and the absorber film can be formed by a known method as described previously.

### <Method for Producing Reflective Mask and Reflective Mask>

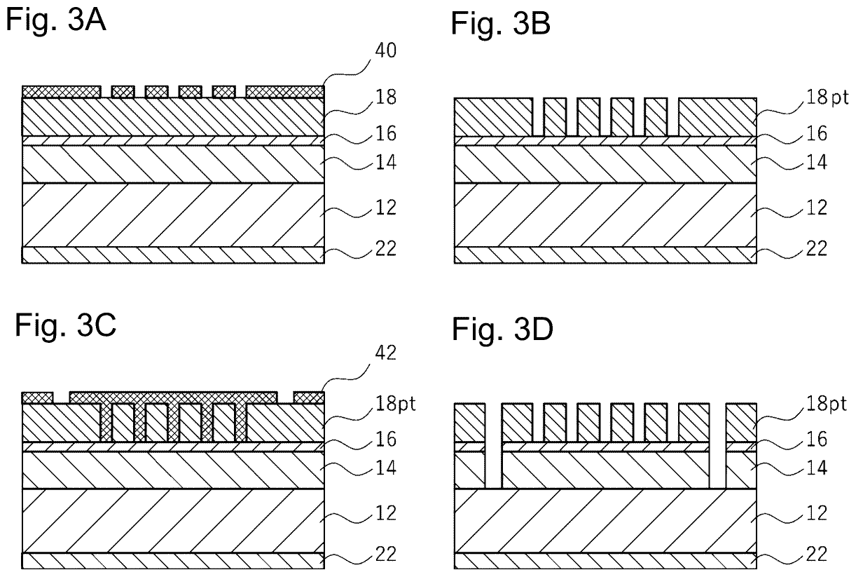

The reflective mask of the present invention is obtained by patterning the absorber film of the reflective mask blank of the present invention. An example of a method for producing the reflective mask will be described below by referring to FIGS. 3A-3D.

FIG. 3A shows a reflective mask blank comprising a conductive film 22, a substrate 12, a capping film 16, an absorber film 18, a hard mask film 20 in this order, and a resist pattern 40 formed on the mask blank. The resist pattern 40 may be formed by a known method, for example, by application of the resist onto the hard mask film 20 of the reflective mask blank followed by exposure to light and development. The resist pattern 40 is designed according to the pattern to be formed on a wafer using the reflective mask.

Then, the absorber film 18 is patterned by etching using the resist pattern 40 shown in FIG. 3A as the mask, and the resist pattern 40 is removed, leaving an absorber pattern 18pt as shown in FIG. 3B.

Then, a resist pattern 42 which defines the frame of the exposure field is formed on the stack shown in FIG. 3B, as shown in FIG. 3C, and the stack is dry-etched to the substrate 12, using the resist pattern 42 shown in FIG. 3C as the mask.

After the dry etching, the resist pattern 42 is removed to obtain a reflective mask shown in FIG. 3D.

The reflective mask obtained by patterning the absorber film of the reflective mask blank of the present invention is suitable as a reflective mask used for EUV exposure.

### EXAMPLES

Now, the present invention will be described in further detail in reference to Examples.

The species, amounts and proportions of the materials, operations and procedures for operations used in the following Examples may be changed as appropriately without departing from the spirit and scope of the present invention. The present invention is therefore by no means restricted to the following Examples.

Here, Examples 1, 2 and 5 are Examples of the present invention, and Examples 3, 4, 6 and 7 are Comparative Examples.

### Example 1

A procedure for producing a substrate with a conductive film of Example 1 will be representatively described below.

### [Substrate]

As the substrate, a SiO₂—TiO₂ glass plate (6 inch (152 mm) square and 6.3 mm thick) was used. The glass substrate had a thermal expansion coefficient of 0.02×10⁻⁷/° C., a Young's modulus of 67 GPa, a Poisson's ratio of 0.17 and a specific rigidity of 3.07×10⁷ m²/s². The first main surface of the glass substrate had a quality area polished to a root mean square roughness (Rq) of 0.15 nm or less and a flatness of 100 nm or less.

### [Conductive Film]

On one side of the substrate, a TaN film (as a conductive film) was formed by magnetron sputtering under the following conditions.
Target: metallic Ta target
Sputtering gas: mixed gas comprising Ar gas and N₂ gas (Ar gas: 81 vol %, N₂ gas: 19 vol %)
Sputtering Pressure: 0.23 Pa
Power Input: 1000 W
Deposition Rate: 4.62 nm/min

The substrate with a conductive film of Example 1 thus obtained was analyzed as described below.

### [Measurements]

### (Composition of Conductive Film)

The composition of the conductive film thus formed was analyzed by XPS.

For XPS, “PHI 5000 VersaProbe” manufactured by ULVAC-PHI, INCORPORATED. was used.

The results of the composition analysis are shown in the table below. The element contained in the target accounted for the remaining portion of the composition not shown in the table.

### (Thickness)

The thickness of the conductive film was measured as described previously.

Namely, XRR measurements were made at points expressed as (0, 0), (33, 33) and (66, 66) in a coordinate system with the coordinate origin at the intersection of the diagonals of the substrate, and the thickness of the conductive film (arithmetic mean), the thickness of the conductive film at the center of the substrate, the thickness of the conductive film at the peripheral portion of the substrate and the maximum in-plane thickness variation of the conductive film were calculated.

### Examples 2 TO 7

Substrates with a conductive film were obtained in the same manner as in Example 1 except that the conditions were changed as shown later in the table.

The measurement results are shown in the table below.

In Examples 2 and 5, a conductive film 1 was formed first, and then a conductive film 2 was formed. The composition of the conductive film 1 was analyzed after the conductive film 2 was removed by argon ion sputtering from a region of the conductive film 1 to be analyzed by XPS.

### <Evaluation Methods and Ratings>

With the substrates with a conductive film thus obtained, the light transmittance variation of the conductive films at 632 nm, flatness, electric resistivity and surface roughness were evaluated by the methods and ratings described below.

### [Transmittance Variation]

The transmittance variations at 632 nm and at 1064 nm were determined by the previously mentioned methods.

Namely, the transmittance at each wavelength was measured at the above-mentioned three points where the thickness of the conductive film was measured with a spectrophotometer (U-4100 manufactured by Hitachi High-Tech Corporation), and the average transmittance at each wavelength and the maximum transmittance difference at each wavelength, which is defined as the difference between the maximum and minimum transmittance values at these three points, were calculated.

The transmittance variation at each wavelength was rated on the following scale based on the ratio of the maximum transmittance difference to the average transmittance. The results are shown in the table below.
A: The ratio of the maximum transmittance difference to the average transmittance at 632 nm is less than 2.0%, and the ratio of the maximum transmittance difference to the average transmittance at 1064 nm is less than 2.0%.
B: The criterion for A is not met.

### [Flatness]

The flatness of a substrate with a conductive film was evaluated as described below.

The flatness of a substrate with a conductive film was measured with a FUJINON flatness interferometer and rated on the following scale. The results are shown in the table below.
A: flatness of 0.4 μm or more
B: flatness of less than 0.4 μm

The rating A means that the substrate with a conductive film is warped. A warped substrate with a conductive film can make a flatter reflective mask blank when a multilayer reflective film and an absorber film are formed on the side of the substrate opposite to the conductive film, because the stresses generated by formation of the multilayer reflective film and the absorber film balance out the warping of the substrate with a conductive film.

### [Electric Resistivity]

The electric resistivity of a substrate with a conductive film was determined as described below. For calculation of electric resistivity, the thickness of the conductive film measured as described above was used. The results are shown in the table below.
Instrument: Loresta-GX manufactured by Nittoseiko Analytech Co., Ltd.
Measurement points: 3 points
Measured Area: 149 mm×149 mm

### [Surface Roughness]

The surface roughness (root mean square roughness Rq) of the surface of the conductive film opposite to the substrate was determined by analyzing a surface image of the size of 2 μm×2 μm under an atomic force microscope manufactured by Seiko Instruments Inc. The results are shown in the table below.

### Results

The constituents of the respective substrates with a conductive film and the measurement and evaluation results are shown in the table.

In the row “thickness at center>thickness at peripheral portion” in the table, “A” means that the thickness of the conductive film at the center was larger than the thickness of the conductive film at the peripheral portion, and “B” means that the criterion for A was not met.

TABLE 1

| | | | Ex. 1 | Ex. 2 | | Ex. 3 | Ex. 4 |
|---|---|---|---|---|---|---|---|
| Structure of conductive film | | | Monolayer | Conductive | Conductive | Monolayer | Monolayer |
| | | | | film 1 | film 2 | | |
| Film | Target | | Ta | Ta | Ta | Ta | Ta |
| forming | Feed gas | Ar (vol %) | 81 | 81 | 40 | 90 | 83 |
| conditions | | N₂ (vol %) | 19 | 19 | — | 10 | 17 |
| | | O₂ (vol %) | — | — | 60 | — | — |

| | | | | | |
|---|---|---|---|---|---|
| Pressure (Pa) | 0.23 | 0.23 | 0.05 | 0.12 | 0.23 |
| Deposition rate (nm/sec) | 0.077 | 0.077 | 0.140 | 0.100 | 0.083 |

| Composition | N (atomic %) | 48 | 48 | — | 21 | 33 |
|---|---|---|---|---|---|---|
| | O (atomic %) | — | — | 42 | — | — |
| | B (atomic %) | — | — | — | — | — |
| | N content (atomic %) | 48 | 41 | | 21 | 33 |
| | relative to all the atoms | | | | | |
| | in conductive film | | | | | |
| Thickness | Thickness | 61 | 62 | 10 | 56 | 61 |
| | Thickness at center > | A | A | | B | A |
| | thickness at peripheral | | | | | |
| | portion | | | | | |
| | Maximum thickness | 0.58 | 0.58 | | 0.93 | 0.71 |
| | variation (nm) | | | | | |

| | | | | | | |
|---|---|---|---|---|---|---|
| Evaluation | Transmittance | 632 nm (%) | 1.0 | 1.1 | 4.3 | 1.2 |
| | variation | 1064 nm (%) | 1.1 | 0.9 | 2.7 | 1.7 |
| | | Evaluation | A | A | B | A |

| | | | | |
|---|---|---|---|---|
| Flatness rating | A | A | A | B |
| Electric resistivity (mΩ · cm) | 0.271 | 0.336 | 0.23 | 0.290 |
| Surface roughness (nm) | 0.41 | 0.41 | 0.08 | 0.43 |

| | | | Ex. 5 | | Ex. 6 | Ex. 7 |
|---|---|---|---|---|---|---|
| Structure of conductive film | | | Conductive | Conductive | Monolayer | Monolayer |
| | | | film 1 | film 2 | | |
| Film | Target | | Ta | Ta | Ta | Ta |
| forming | Feed gas | Ar (vol %) | 81 | 48 | 80 | 80 |
| conditions | | N₂ (vol %) | 19 | — | 20 | 20 |
| | | O₂ (vol %) | — | 52 | — | — |

| | | | | |
|---|---|---|---|---|
| Pressure (Pa) | 0.23 | 0.04 | 0.22 | 0.27 |
| Deposition rate (nm/sec) | 0.077 | 0.119 | 0.091 | 0.081 |

| Composition | N (atomic %) | 48 | — | 49 | 49 |
|---|---|---|---|---|---|
| | O (atomic %) | — | 20 | — | — |
| | B (atomic %) | — | — | — | — |
| | N content (atomic %) | 41 | | 49 | 49 |
| | relative to all the atoms | | | | |
| | in conductive film | | | | |
| Thickness | Thickness | 62 | 10 | 63 | 56 |

| Thickness at center > | A | A | A |
|---|---|---|---|
| thickness at peripheral | | | |
| portion | | | |
| Maximum thickness | 0.4 | 0.2 | 1.2 |
| variation (nm) | | | |

| | | | | | |
|---|---|---|---|---|---|
| Evaluation | Transmittance | 632 nm (%) | 1.8 | 4.7 | 2.8 |
| | variation | 1064 nm (%) | 1.6 | 7.4 | 2.5 |
| | | Evaluation | A | B | B |

| | | | |
|---|---|---|---|
| Flatness rating | A | A | A |
| Electric resistivity (mΩ · cm) | 0.281 | 0.265 | 0.409 |
| Surface roughness (nm) | — | — | — |

As demonstrated in Table 1, conductive films which satisfied all the requirements described so far had a small transmittance variation. The flatness of substrates with a conductive film which satisfies all the requirements described so far is not too high, and such substrates with a conductive film can make reflective mask blanks with excellent flatness.

In Example 3, because the conductive film was not thicker at the center of the substrate than at the peripheral portion of the substrate, the transmittance variation of the conductive film was not small.

In Example 4, because the total content of nitrogen and boron in a conductive film was 33% or below relative to all the atoms in the conductive film, the substrate with such a conductive film had too high flatness to make a reflective mask blank with high flatness.

The substrates with a conductive film obtained above can make the reflective mask blank of the present invention when a multilayer reflective film and an absorber film are formed on a surface of each of the substrates with a conductive film thus obtained opposite to the conductive film as described above.

### REFERENCE SYMBOLS

10: Reflective mask blank
12: Substrate
14: Multilayer reflective film
16: Capping film
18: Absorber film
18pt: Absorber pattern
22: Conductive film
40, 42: Resist pattern

What is claimed is:

1. A reflective mask blank for EUV lithography comprising:
a substrate;
a conductive film provided on one side of the substrate;
a multilayer reflective film to reflect EUV light, provided on the other side of the substrate; and
an absorber film provided on a side of the multilayer reflective film opposite to the substrate,
wherein the conductive film comprises at least one element selected from the group consisting of tantalum and chromium,
wherein the total content of nitrogen and boron in the conductive film is more than 33 atomic % relative to all the atoms in the conductive film,
wherein the conductive film has a thickness of from 20 to 150 nm,
wherein the conductive film is thicker at the center of the substrate than at a peripheral portion of the substrate, and
wherein the maximum in-plane thickness variation of the conductive film is from 0.30 to 1.00 nm.

2. The reflective mask blank for EUV lithography according to claim 1, wherein the content of nitrogen in the conductive film is from 35 to 65 atomic % relative to all the atoms in the conductive film.

3. The reflective mask blank for EUV lithography according to claim 1, wherein the content of boron in the conductive film is more than 0 atomic % and at most 35 atomic % relative to all the atoms in the conductive film.

4. The reflective mask blank for EUV lithography according to claim 1, wherein the conductive film has an electric resistivity of from 0.05 to 0.35 mQ-cm.

5. The reflective mask blank for EUV lithography according to claim 1, wherein the surface roughness of the surface of the conductive film opposite to the substrate is at most 0.60 nm.

6. The reflective mask blank for EUV lithography according to claim 1, wherein the conductive film has a multilayer structure comprising at least two layers including an outermost layer comprising tantalum and at least one element selected from the group consisting of nitrogen and oxygen located farthest from the substrate.

7. The reflective mask blank for EUV lithography according to claim 6, wherein the content of oxygen in the outermost layer is from 20 to 60 atomic % relative to all the atoms in the outermost layer.

8. The reflective mask blank for EUV lithography according to claim 6, wherein the content of oxygen in the outermost layer is from 40 to 50 atomic % relative to all the atoms in the outermost layer.

9. The reflective mask blank for EUV lithography according to claim 1, wherein when the light transmittance of the conductive film is measured at different three points at 632 nm, the arithmetic mean of the transmittance values thus obtained at these three points is designated as the average transmittance at 632 nm, and the difference between the maximum and minimum transmittance values at these three points is designated as the maximum transmittance difference at 632 nm, the ratio of the maximum transmittance difference of the conductive film at 632 nm to the average transmittance of the conductive film at 632 nm is less than 2.0%.

10. The reflective mask blank for EUV lithography according to claim 1, wherein when the light transmittance of the conductive film measured at different three points at 1064 nm, the arithmetic mean of the transmittance values thus obtained at these three points is designated as the average transmittance at 1064 nm, and the difference between the maximum and minimum transmittance values at these three points is designated as the maximum transmittance difference at 1064 nm, the ratio of the maximum transmittance difference of the conductive film at 1064 nm to the average transmittance of the conductive film at 1064 nm is less than 2.0%.

11. A reflective mask for EUV lithography having an absorber pattern obtained by patterning the absorber film of the reflective mask blank for EUV lithography as defined in claim 1.

12. A method for producing a reflective mask for EUV lithography, comprising a step of patterning the absorber film of the reflective mask blank for EUV lithography as defined in claim 1.

13. A method for producing a reflective mask blank for EUV lithography as defined in claim 1, comprising forming a conductive film on one surface of a substrate,
forming a multilayer reflective film which reflects EUV light on the other surface of the substrate, and
forming an absorber film on the surface of the multilayer reflective film opposite to the substrate,
wherein the conductive film is formed in the presence of nitrogen gas under a pressure of 0.1 to 0.4 Pa

14. A substrate with a conductive film, comprising a substrate; and
a conductive film provided on one surface of the substrate,
wherein the conductive film comprises at least one element selected from the group consisting of tantalum and chromium,
wherein the total content of nitrogen and boron in the conductive film is more than 33 atomic % relative to all the atoms in the conductive film,
wherein the conductive film has a thickness of from 20 to 150 nm,
wherein the conductive film is thicker at the center of the substrate than at the peripheral portion of the substrate, and
wherein the maximum in-plane thickness variation of the conductive film is from 0.30 to 1.00 nm.

15. The substrate with a conductive film according to claim 14, wherein the content of nitrogen in the conductive film is from 35 to 65 atomic % relative to all the atoms in the conductive film.

16. The substrate with a conductive film according to claim 14, wherein the content of boron in the conductive film is more than 0 atomic % and at most 35 atomic % relative to all the atoms in the conductive film.

17. The substrate with a conductive film according to claim 14, wherein the conductive film has an electric resistivity of from 0.05 to 0.35 mQ-cm.

18. The substrate with a conductive film according to claim 14, wherein the conductive film has a multilayer structure comprising at least two layers including an outermost layer comprising at least one element selected from the group consisting of tantalum, nitrogen and oxygen located farthest from the substrate.

19. The substrate with a conductive film according to claim 18, wherein the content of oxygen in the outermost layer is from 20 to 60 atomic % relative to all the atoms in the outermost layer.

20. The substrate with a conductive film according to claim 18, wherein the content of oxygen in the outermost layer is from 40 to 50 atomic % relative to all the atoms in the outermost layer.

21. The substrate with a conductive film according to claim 14, wherein when the light transmittance of the conductive film measured at different three points at 632 nm, the arithmetic mean of the transmittance values thus obtained at these three points is designated as the average transmittance at 632 nm, and the difference between the maximum and minimum transmittance values at these three points is designated as the maximum transmittance difference at 632 nm, the ratio of the maximum transmittance difference of the conductive film at 632 nm to the average transmittance of the conductive film at 632 nm is less than 2.0%.

22. The substrate with a conductive film according to claim 14, wherein when the light transmittance of the conductive film measured at different three points at 1064 nm, the arithmetic mean of the transmittance values thus obtained at these three points is designated as the average transmittance at 1064 nm, and the difference between the maximum and minimum transmittance values at these three points is designated as the maximum transmittance difference at 1064 nm, the ratio of the maximum transmittance difference of the conductive film at 1064 nm to the average transmittance of the conductive film at 1064 nm is less than 2.0%.
